(19) United States
(12) Patent Application Publication
(10) Pub. No.: US 2024/0422978 A1
(43) Pub. Date: Dec. 19, 2024

(54) SEMICONDUCTOR DEVICE AND MANUFACTURING METHOD OF THE SAME

(71) Applicant: Kioxia Corporation, Tokyo (JP)

(72) Inventors: Kazuki MATSUNAGA, Yokkaichi Mie (JP); Shinya OKUDA, Yokkaichi Mie (JP); Shuichi TSUBATA, Kuwana Mie (JP)

(73) Assignee: Kioxia Corporation, Tokyo (JP)

(21) Appl. No.: 18/740,746

(22) Filed: Jun. 12, 2024

(30) Foreign Application Priority Data
Jun. 19, 2023 (JP) 2023-100354

(51) Int. Cl. H10B 43/27; H10B 41/27

(52) U.S. Cl. CPC H10B 43/27; H10B 41/27

(57) ABSTRACT

A semiconductor device includes a stacked film including electrode layers and first insulating films alternately stacked in a first direction, wherein the stacked film includes a first portion with a non-stepped shape and a second portion with a stepped shape; a second insulating film provided on the second portion; a columnar portion extending through the first portion and including a charge storage layer; a third insulating film extending through the second portion and the second insulating film; a plug provided on any of the electrode layers in the second portion; and a first region provided in the second portion and the second insulating film and including an element. A concentration of the element in the first region is higher than a concentration of the element in a region outside the first region in the second insulating film.

### CROSS-REFERENCE TO RELATED APPLICATION(S)

This application is based upon and claims the benefit of priority from Japanese Patent Application No. 2023-100354, filed Jun. 19, 2023, the entire contents of which are incorporated herein by reference.

### FIELD

Embodiments described herein relate generally to a semiconductor device and a manufacturing method of the same.

### BACKGROUND

When a recess is formed in or on a stacked film of a three-dimensional semiconductor memory, bowing of the recess may become large. For example, when a hole for a beam portion is formed in a stepped portion of the stacked film, bowing of the hole becomes large in many cases.

### DESCRIPTION OF THE DRAWINGS

FIG. 1 is a cross-sectional view showing a structure of a semiconductor device according to a first embodiment.

FIG. 2 is an enlarged cross-sectional view showing the structure of the semiconductor device according to the first embodiment.

FIG. 3 is a cross-sectional view (1/11) showing a manufacturing method of the semiconductor device according to the first embodiment.

FIG. 4 is a cross-sectional view (2/11) showing the manufacturing method of the semiconductor device according to the first embodiment.

FIG. 5 is a cross-sectional view (3/11) showing the manufacturing method of the semiconductor device according to the first embodiment.

FIG. 6 is a cross-sectional view (4/11) showing the manufacturing method of the semiconductor device according to the first embodiment.

FIG. 7 is a cross-sectional view (5/11) showing a manufacturing method of the semiconductor device according to the first embodiment.

FIG. 8 is a cross-sectional view (6/11) showing the manufacturing method of the semiconductor device according to the first embodiment.

FIG. 9 is a cross-sectional view (7/11) showing the manufacturing method of the semiconductor device according to the first embodiment.

FIG. 10 is a cross-sectional view (8/11) showing the manufacturing method of the semiconductor device according to the first embodiment.

FIG. 11 is a cross-sectional view (9/11) showing the manufacturing method of the semiconductor device according to the first embodiment.

FIG. 12 is a cross-sectional view (10/11) showing the manufacturing method of the semiconductor device according to the first embodiment.

FIG. 13 is a cross-sectional view (11/11) showing the manufacturing method of the semiconductor device according to the first embodiment.

FIG. 14 is a cross-sectional view (1/7) showing a manufacturing method of the semiconductor device according to a second embodiment.

FIG. 15 is a cross-sectional view (2/7) showing the manufacturing method of the semiconductor device according to the second embodiment.

FIG. 16 is a cross-sectional view (3/7) showing the manufacturing method of the semiconductor device according to the second embodiment.

FIG. 17 is a cross-sectional view (4/7) showing the manufacturing method of the semiconductor device according to the second embodiment.

FIG. 18 is a cross-sectional view (5/7) showing the manufacturing method of the semiconductor device according to the second embodiment.

FIG. 19 is a cross-sectional view (6/7) showing the manufacturing method of the semiconductor device according to the second embodiment.

FIG. 20 is a cross-sectional view (7/7) showing the manufacturing method of the semiconductor device according to the second embodiment.

FIG. 21 is a cross-sectional view showing a structure of the semiconductor device according to a third embodiment.

FIG. 22 is a cross-sectional view (1/4) showing the manufacturing method of the semiconductor device according to the third embodiment.

FIG. 23 is a cross-sectional view (2/4) showing the manufacturing method of the semiconductor device according to the third embodiment.

FIG. 24 is a cross-sectional view (3/4) showing the manufacturing method of the semiconductor device according to the third embodiment.

FIG. 25 is a cross-sectional view (4/4) showing the manufacturing method of the semiconductor device according to the third embodiment.

### DETAILED DESCRIPTION

Embodiments provide a semiconductor device in which bowing is capable of being reduced, and a manufacturing method of the same.

In general, according to one embodiment, a semiconductor device includes a stacked film including a plurality of electrode layers and a plurality of first insulating films alternately stacked in a first direction, wherein the stacked film includes a first portion with a non-stepped shape and a second portion with a stepped shape; a second insulating film provided on the second portion; a columnar portion extending through the first portion in the first direction and including a charge storage layer and a semiconductor layer; a third insulating film extending through the second portion and the second insulating film in the first direction; a plug provided on any of the electrode layers in the second portion; and a first region provided in the second portion and the second insulating film and including a first element. A concentration of the first element in the first region is higher than a concentration of the first element in a region outside the first region in the second insulating film, and at least one of the third insulating film or the plug is in contact with the first region.

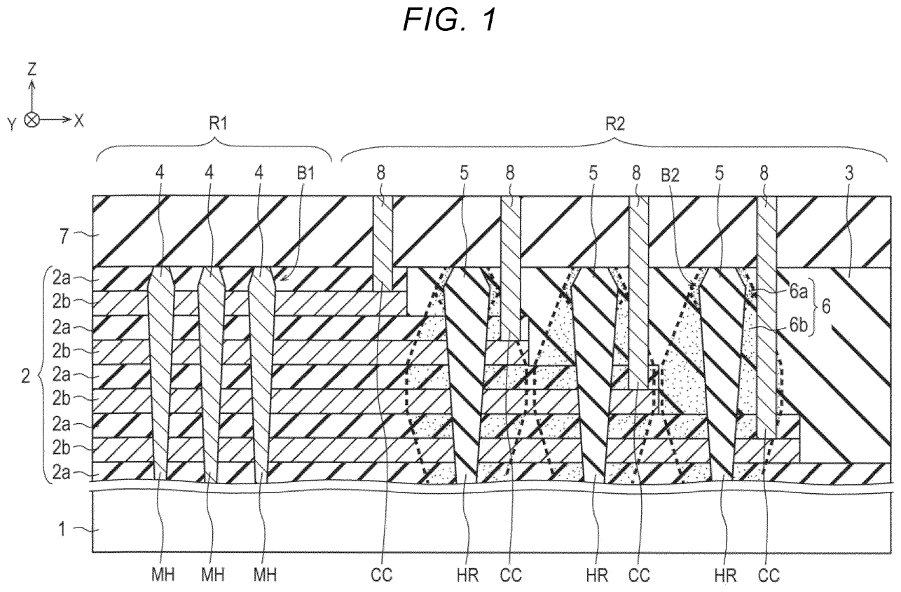

Hereinafter, embodiments of the present disclosure will be described with reference to drawings. In FIGS. 1 to 25, the same components are denoted by the same reference symbols, and redundant description will be omitted.

### First Embodiment

FIG. 1 is a cross-sectional view showing a structure of a semiconductor device according to a first embodiment. The semiconductor device according to the present embodiment includes, for example, a three-dimensional semiconductor memory.

The semiconductor device according to the present embodiment includes a substrate 1, a stacked film 2, an interlayer insulating film 3, a plurality of columnar portions 4, a plurality of beam portions 5, a plurality of impurity regions 6, an interlayer insulating film 7, and a plurality of contact plugs 8. The stacked film 2 includes a plurality of insulating films 2a and a plurality of electrode layers 2b. Each impurity region 6 includes an impurity region 6a and an impurity region 6b. The insulating film 2a, the interlayer insulating film 3, and the beam portion 5 are examples of a first insulating film, a second insulating film, and a third insulating film, respectively. The impurity regions 6, 6a, and 6b are examples of a first region, an upper region, and a lower region, respectively.

The substrate 1 is, for example, a semiconductor substrate such as a silicon (Si) substrate. FIG. 1 shows X and Y directions parallel to a surface of the substrate 1 and perpendicular to each other, and a Z direction perpendicular to the surface of the substrate 1. The X direction, the Y direction, and the Z direction intersect each other. In the present specification, a +Z direction is regarded as an upward direction, and a −Z direction is regarded as a downward direction. The −Z direction may or may not coincide with a gravity direction. The Z direction is an example of the first direction.

The stacked film 2 is formed on the substrate 1. The stacked film 2 may be formed directly on the substrate 1, or may be formed on the substrate 1 with another film interposed therebetween. The stacked film 2 includes the plurality of insulating films 2a and the plurality of electrode layers 2b alternately stacked in the Z direction. Each insulating film 2a is, for example, a silicon oxide film (SiO₂ film). Each electrode layer 2b is, for example, a metal layer including a tungsten (W) layer. Each electrode layer 2b functions as, for example, a word line or a selection line of a three-dimensional semiconductor memory.

The stacked film 2 includes a flat portion R1 having a non-stepped shape and a stepped portion R2 having a stepped shape. The stepped shape includes a stair structure. The flat portion R1 has a flat upper surface. The stepped portion R2 has an upper surface and a side surface processed into a stepped shape. Each of the flat portion R1 and the stepped portion R2 includes the plurality of insulating films 2a and the plurality of electrode layers 2b described above. The flat portion R1 and the stepped portion R2 are examples of a first portion and a second portion, respectively.

The semiconductor device according to the present embodiment may be manufactured by forming the stacked film 2 on the substrate 1, bonding the substrate 1 to another substrate, and then removing the substrate 1. In this case, the semiconductor device according to the present embodiment may not include the substrate 1. In addition, in this case, the +Z direction may be the downward direction and the −Z direction may be the upward direction.

The interlayer insulating film 3 is formed on the stepped portion R2 of the stacked film 2. The interlayer insulating film 3 is, for example, a SiO₂ film. In the present embodiment, an upper surface of the interlayer insulating film 3 is located at the same height as the upper surface of the flat portion R1 of the stacked film 2.

Each columnar portion 4 is formed in a memory hole MH penetrating the flat portion R1, and has a columnar shape extending in the Z direction. As described below, each columnar portion 4 includes a block insulating film, a charge storage layer, a tunnel insulating film, a channel semiconductor layer, and a core insulating film, which are sequentially formed on a side surface of the memory hole MH. Each columnar portion 4 forms a plurality of memory cells of the three-dimensional semiconductor memory together with the plurality of electrode layers 2b. The memory hole MH is an example of a first recess.

Each beam portion 5 is formed in a beam hole HR penetrating the stepped portion R2 and the interlayer insulating film 3, and has a columnar shape extending in the Z direction. Each beam portion 5 is, for example, an insulating film such as a SiO₂ film. Each beam portion 5 functions as a beam for preventing the stacked film 2 from collapsing when a plurality of sacrificial layers in the stacked film 2 are replaced with the plurality of electrode layers 2b (replacement step), as described below. The beam hole HR is an example of a second recess.

Each impurity region 6 is formed in the stepped portion R2 and the interlayer insulating film 3, and contains a predetermined element. The predetermined element is, for example, an impurity element in the stepped portion R2 and the interlayer insulating film 3. Each impurity region 6 is formed, for example, by implanting ions of the predetermined element into the stepped portion R2 and the interlayer insulating film 3. The predetermined element is, for example, phosphorus (P). The predetermined element may be another element such as boron (B), arsenic (As), silicon (Si), or nitrogen (N). The predetermined element is an example of a first element.

FIG. 1 shows an outline of each impurity region 6 with a broken line. FIG. 1 shows three impurity regions 6 formed around three beam portions 5, respectively. Each beam portion 5 is in contact with a corresponding impurity region 6, and more specifically, the each beam portion 5 is formed in the corresponding impurity region 6. FIG. 1 schematically shows P atoms in each impurity region 6 by dot hatching in each impurity region 6. As is clear from the dot hatching in FIG. 1, the P atoms of the present embodiment are provided in the interlayer insulating film 3 and the insulating film 2a, but are not provided in the electrode layer 2b. This is because the sacrificial layer was replaced with the electrode layer 2b after the P atoms were implanted in the insulating film 2a and the sacrificial layer. Then, although each impurity region 6 is divided into a plurality of impurity regions by the electrode layer 2b, these impurity regions were one impurity region before the division, and thus, in the present embodiment, the region (=each impurity region 6) surrounded by the broken line in FIG. 1 is regarded as one impurity region.

Each impurity region 6 includes the impurity region 6a formed in at least the interlayer insulating film 3 and the impurity region 6b formed in at least the stepped portion R2. In each impurity region 6, the impurity region 6b is located below the impurity region 6a. In the present embodiment, the impurity region 6a is formed only in the interlayer insulating film 3, and the impurity region 6b is formed in the interlayer insulating film 3 and the stepped portion R2. Meanwhile, the impurity region 6a may be formed in the interlayer insulating film 3 and the stepped portion R2. In addition, the impurity region 6b may be formed only in the interlayer insulating film 3. Each beam portion 5 is in contact with the impurity region 6a and the impurity region 6b in the corresponding impurity region 6, and more specifically, each beam portion 5 is formed in the impurity region 6a and the impurity region 6b of the corresponding impurity region 6.

The impurity region 6a contains the P atoms at a high concentration, and the impurity region 6b contains the P atoms at a low concentration. Therefore, the concentration of the P atoms in the impurity region 6b is lower than the concentration of the P atoms in the impurity region 6a. The concentration of the P atoms in the impurity region 6a is, for example, 1.0×10²¹ to 1.0×10²² atoms/cm³. The concentration of the P atoms in the impurity region 6b is, for example, 1.0×10²⁰ to 5.0×10²¹ atoms/cm³. The concentration of the P atoms in the impurity region 6a and the concentration of the P atoms in the impurity region 6b are examples of first and second concentrations, respectively.

A region outside the impurity region 6 in the interlayer insulating film 3 may not contain the P atoms at all, or may contain the P atoms having a lower concentration than the impurity regions 6a and 6b. Similarly, a region outside the impurity region 6 in the stacked film 2 may not contain the P atoms at all, or may contain the P atoms having a lower concentration than the impurity regions 6a and 6b. This also applies when the impurity atoms are atoms other than the P atoms.

The interlayer insulating film 7 is formed on the stacked film 2, the interlayer insulating film 3, the columnar portion 4, the beam portion 5, and the impurity region 6. The interlayer insulating film 7 is, for example, a SiO₂ film.

Each contact plug 8 is formed in a contact hole CC penetrating one insulating film 2a in the stepped portion R2 and the interlayer insulating films 3 and 7, and has a columnar shape extending in the Z direction. Therefore, each contact plug 8 is formed on one electrode layer 2b in the stepped portion R2 and is electrically connected to the electrode layer 2b. Meanwhile, the leftmost contact plug 8 in FIG. 1 penetrates one insulating film 2a in the stepped portion R2 and the interlayer insulating film 7, and does not penetrate the interlayer insulating film 3. The insulating film 2a through which the contact plug 8 penetrates may be regarded as the insulating film 2a in the flat portion R1. Each contact plug 8 is, for example, a metal layer including a W layer, an aluminum (Al) layer, or a copper (Cu) layer. The contact hole CC is an example of a third recess.

In the present embodiment, each contact plug 8 is in contact with a corresponding impurity region 6 (excluding the leftmost contact plug 8 in FIG. 1). Each contact plug 8 may be in contact with only one of the impurity regions 6a and 6b, or may be in contact with both the impurity regions 6a and 6b. In addition, each contact plug 8 may be formed in the corresponding impurity region 6 or may not be formed in the corresponding impurity region 6. In the former case, each contact plug 8 may be formed in the impurity region 6a and the impurity region 6b, or may be formed in the impurity region 6a or the impurity region 6b. In FIG. 1, two contact plugs 8 are formed in the impurity region 6b, and one contact plug 8 is in contact with the impurity region 6b but is formed outside the impurity region 6b. That is, the two contact plugs 8 are annularly surrounded by the impurity region 6b, and the one contact plug 8 is not annularly surrounded by the impurity region 6b.

Each contact plug 8 may not be formed in the interlayer insulating film 7. That is, each contact plug 8 may be formed in the contact hole CC penetrating one insulating film 2a in the stepped portion R2 and the interlayer insulating film 3, or in the contact hole CC penetrating one insulating film 2a in the stepped portion R2. An example of such a contact plug 8 will be described in a third embodiment described below.

Next, with continued reference to FIG. 1, bowing of the memory hole MH and the beam hole HR will be described.

When the memory hole MH is formed by etching such as reactive ion etching (RIE), bowing may occur in which the side surface of the memory hole MH protrudes in a radial direction. The bowing occurs when side etching progresses on the side surface of the memory hole MH. This also applies when forming the beam hole HR. In FIG. 1, the bowing of the memory hole MH is indicated by an arrow B1, and the bowing of the beam hole HR is indicated by an arrow B2. More specifically, the arrow B1 indicates a height at which a diameter of the memory hole MH is maximized, and the arrow B2 indicates a height at which a diameter of the beam hole HR is maximized. When the bowing occurs in the memory hole MH or the beam hole HR, a shape of the columnar portion 4 or the beam portion 5 is affected by the bowing.

In general, the bowing is more likely to occur in a SiO₂ film than in a silicon nitride film (SiN film). The memory hole MH of the present embodiment is formed in the insulating film 2a and the sacrificial layer of the stacked film 2, and the beam hole HR of the present embodiment is formed in the insulating film 2a and the sacrificial layer of the stacked film 2 and in the interlayer insulating film 3. As described above, the insulating film 2a and the interlayer insulating film 3 are, for example, SiO₂ films. Also, the sacrificial layer is, for example, a SiN film. Therefore, as shown in FIG. 1, the bowing is likely to be larger in the beam hole HR than in the memory hole MH. This is because a proportion of the SiO₂ film in a region where the beam hole HR is formed is generally larger than a proportion of the SiO₂ film in a region where the memory hole MH is formed.

Therefore, as described below, the beam hole HR of the present embodiment is formed after forming the impurity region 6 in the stepped portion R2 and the interlayer insulating film 3, and is formed in the impurity region 6. In this case, an etching rate of the stepped portion R2 and the interlayer insulating film 3 in the impurity region 6 is larger than an etching rate of the stepped portion R2 and the interlayer insulating film 3 outside the impurity region 6. Therefore, according to the present embodiment, by forming the beam hole HR in the impurity region 6, it is possible to reduce the bowing of the beam hole HR. The reason is that since the beam hole HR is capable of being formed at a high speed, the beam hole HR is capable of being completed before the bowing becomes large.

The etching rate of the stepped portion R2 and the interlayer insulating film 3 in the impurity region 6 increases as a P concentration increases. From this viewpoint, it is desirable that the P concentration in the impurity region 6 is made high in the entire impurity region 6. However, when the P concentration in the stepped portion R2 increases, a breakdown voltage of the semiconductor device may deteriorate.

Therefore, the impurity region 6 of the present embodiment may include an impurity region 6a having a high P concentration and an impurity region 6b having a low P concentration. The bowing of the beam hole HR is likely to occur near the upper surface of the interlayer insulating film 3 as shown in FIG. 1. Therefore, by forming the impurity region 6a near the upper surface of the interlayer insulating film 3, it is possible to effectively prevent the bowing of the beam hole HR. Also, the bowing of the beam hole HR also occurs in the stepped portion R2, but is less likely to be larger in the stepped portion R2 than in the interlayer insulating film 3. Therefore, by forming the impurity region 6b below the impurity region 6a, it is possible to prevent the bowing of the beam hole HR while preventing the deterioration of the breakdown voltage of the semiconductor device. As described above, according to the present embodiment, it is possible to achieve both the prevention of the bowing of the beam hole HR and the prevention of the deterioration of the breakdown voltage of the semiconductor device.

Various reasons are considered as the reason why the impurity atoms such as the P atoms increase the etching rate of the stepped portion R2 and the interlayer insulating film 3. For example, it is considered that when impurity atoms are implanted into the SiO₂ film, Si—O bonds in the SiO₂ film are reduced, thereby increasing the etching rate of the SiO₂ film. In addition, it is considered that when N atoms are implanted into the SiO₂ film, the etching rate of the SiO₂ film is increased because properties of the SiO₂ film approach properties of the SiN film. The impurity element used in the present embodiment may be any element as long as it is capable of increasing the etching rate of the stepped portion R2 and the interlayer insulating film 3, and may be, for example, B, As, Si, or N.

In the present embodiment, a height of a lower end of the impurity region 6a is set to be, for example, lower than a height of the upper surface of the interlayer insulating film 3 by about 1 μm. In addition, according to the present embodiment, it is possible to reduce the maximum diameter of the beam hole HR indicated by the arrow B2 by, for example, several tens of % compared to the diameter when the impurity region 6 is not formed. That is, according to the present embodiment, it is possible to reduce the bowing of the beam hole HR.

The bowing of the present embodiment may also occur when forming the contact hole CC. When such bowing is desired to be reduced, the contact hole CC is desirably formed in the impurity regions 6a and 6b. In this case, the impurity regions 6a and 6b for the contact hole CC may be formed separately from the impurity regions 6a and 6b for the beam hole HR. In addition, the contact hole CC may be formed in the impurity regions 6a and 6b for the beam hole HR by increasing a size of the impurity regions 6a and 6b for the beam hole HR.

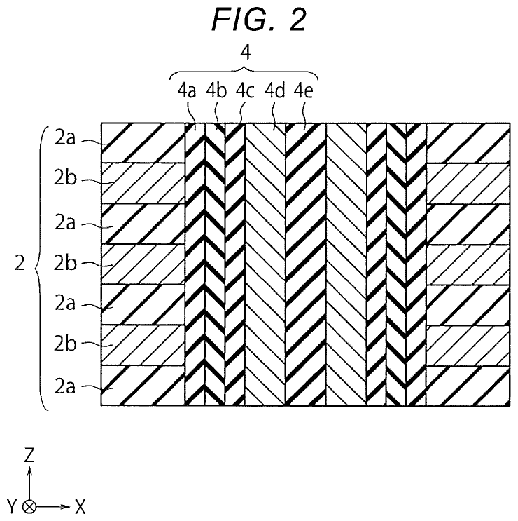

FIG. 2 is an enlarged cross-sectional view showing the structure of the semiconductor device according to the first embodiment.

FIG. 2 shows one of the plurality of columnar portions 4 shown in FIG. 1. Each columnar portion 4 of the present embodiment includes a block insulating film 4a, a charge storage layer 4b, a tunnel insulating film 4c, a channel semiconductor layer 4d, and a core insulating film 4e, which are sequentially formed on a side surface of the stacked film 2. The block insulating film 4a is, for example, a SiO₂ film. The charge storage layer 4b is, for example, an insulating film such as a SiN film. The charge storage layer 4b may be a semiconductor layer such as a polysilicon layer. The tunnel insulating film 4c is, for example, a SiO₂ film. The channel semiconductor layer 4d is, for example, a polysilicon layer. The core insulating film 4e is, for example, a SiO₂ film.

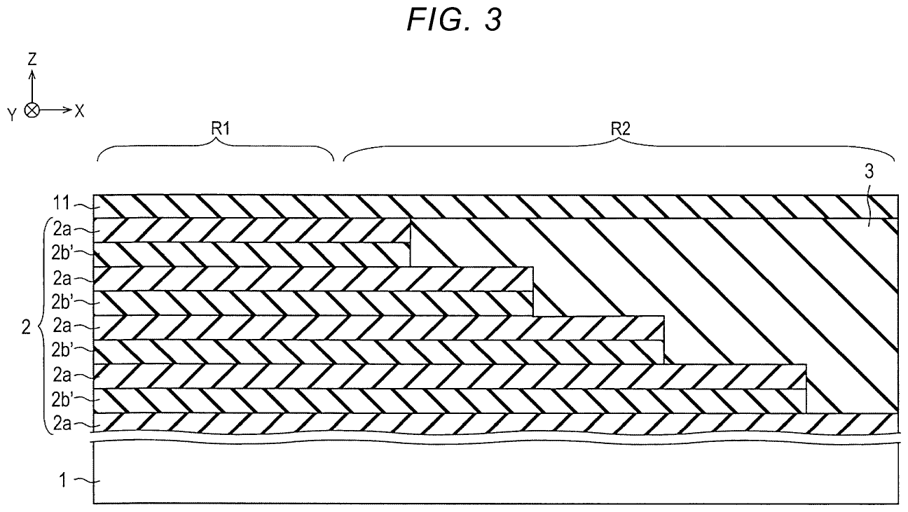

FIGS. 3 to 13 are cross-sectional views showing a manufacturing method of the semiconductor device according to the first embodiment.

First, the stacked film 2 is formed on the substrate 1 (FIG. 3). The stacked film 2 is formed by alternately forming the plurality of insulating films 2a and a plurality of sacrificial layers 2b′ on the substrate 1. The sacrificial layer 2b′ is, for example, a SiN film. The sacrificial layer 2b′ is an example of a first layer. In the present embodiment, the stacked film 2 is formed while processing the stacked film 2 into a step shape. As a result, the stacked film 2 is formed to include a flat portion R1 and a stepped portion R2. In FIG. 3, each of the flat portion R1 and the stepped portion R2 includes the plurality of insulating films 2a and the plurality of sacrificial layers 2b′, which are alternately stacked in the Z direction.

Next, the interlayer insulating film 3 is formed on the stepped portion R2 (FIG. 3). The interlayer insulating film 3 is formed by forming the interlayer insulating film 3 on the flat portion R1 and the stepped portion R2 and polishing a surface of the interlayer insulating film 3 by chemical mechanical polishing (CMP).

Next, a hard mask layer 11 is formed on the flat portion R1 and the interlayer insulating film 3 (FIG. 3). The hard mask layer 11 is, for example, a carbon (C) layer. The hard mask layer 11 is an example of a mask layer.

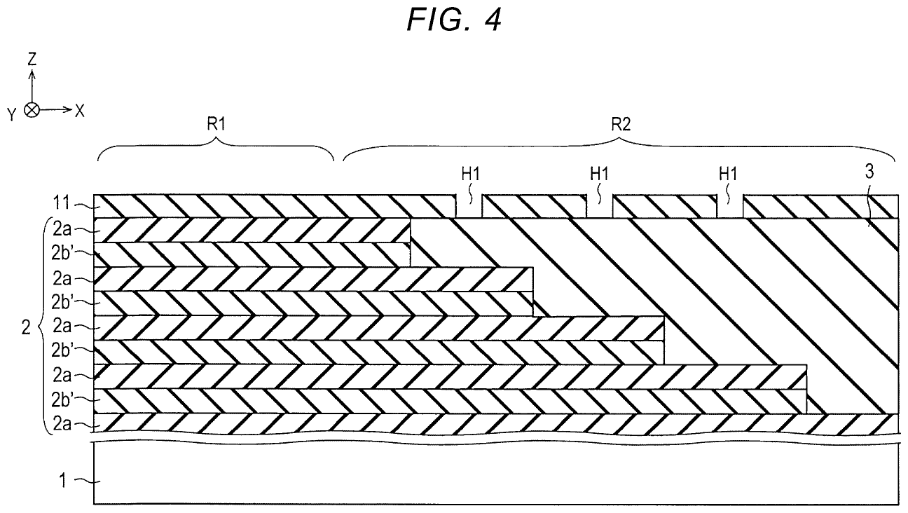

Next, a plurality of openings H1 are formed in the hard mask layer 11 by lithography and RIE (FIG. 4). In FIG. 4, the openings H1 are formed on the interlayer insulating film 3.

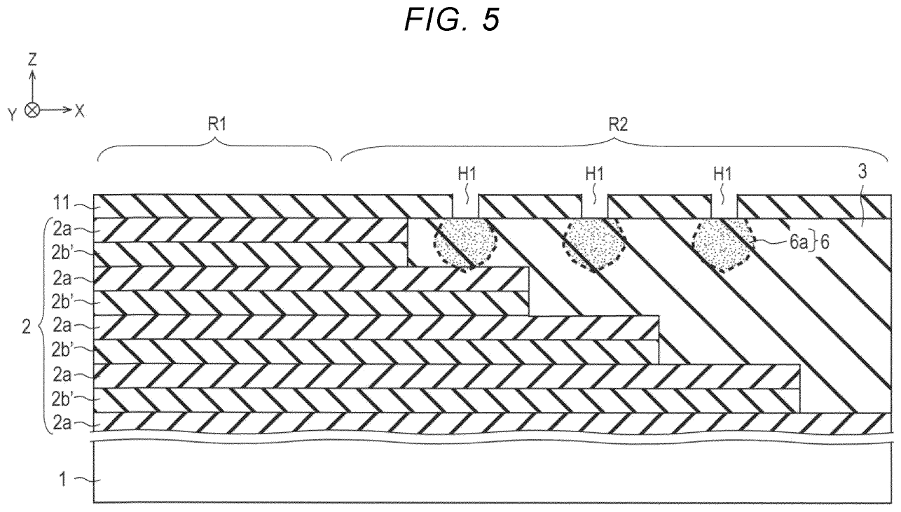

Next, P ions are implanted from the opening H1 into the interlayer insulating film 3 (FIG. 5). As a result, a plurality of the impurity regions 6a containing the P atoms are formed in the interlayer insulating film 3 below the openings H1. At least one of the impurity regions 6a may be formed in the stepped portion R2.

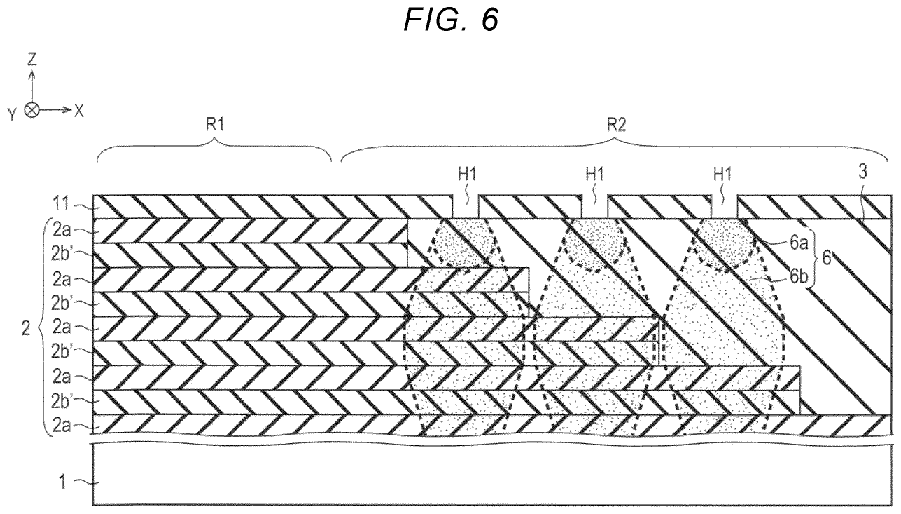

Next, P ions are further implanted from the opening H1 into the interlayer insulating film 3 (FIG. 6). As a result, a plurality of the impurity regions 6b containing the P atoms are formed in the interlayer insulating film 3 and the stepped portion R2 below the impurity regions 6a.

In this way, the plurality of impurity regions 6 are formed in the interlayer insulating film 3 and the stepped portion R2 below the openings H1. Each impurity region 6 is formed to include the impurity region 6a containing the P atoms having a high concentration and the impurity region 6b containing the P atoms having a low concentration. A value of the P concentration in the impurity region 6a is, for example, a value in a range of 1.0×10²¹ to 1.0×10²² atoms/cm³. A value of the P concentration in the impurity region 6b is, for example, a value in a range of 1.0×10²⁰ to 5.0×10²¹ atoms/cm³. In the present embodiment, the etching rate of the stepped portion R2 and the interlayer insulating film 3 in the impurity region 6 is larger than the etching rate of the stepped portion R2 and the interlayer insulating film 3 outside the impurity region 6. In addition, the etching rate of the stepped portion R2 and the interlayer insulating film 3 in the impurity region 6a is larger than the etching rate of the stepped portion R2 and the interlayer insulating film 3 in the impurity region 6b.

In the steps shown in FIGS. 5 and 6, the implantation of the P ions is performed by using source gas containing the P atoms. Examples of the source gas include PF₃ gas and PH₃ gas (F represents fluorine and H represents hydrogen). In the stepped portion R2, the P ions are implanted into the insulating film 2a and the sacrificial layer 2b′. Therefore, each impurity region 6 in the stepped portion R2 is formed not only in the insulating film 2a but also in the sacrificial layer 2b′.

In the steps of FIGS. 5 and 6, ions other than the P ions may be implanted. Examples of such ions include B ions, As ions, Si ions, and N ions. Examples of the source gas in these cases include BF₃ gas, B₂H₆ gas, AsH₃ gas, SiF₄ gas, and N₂ gas.

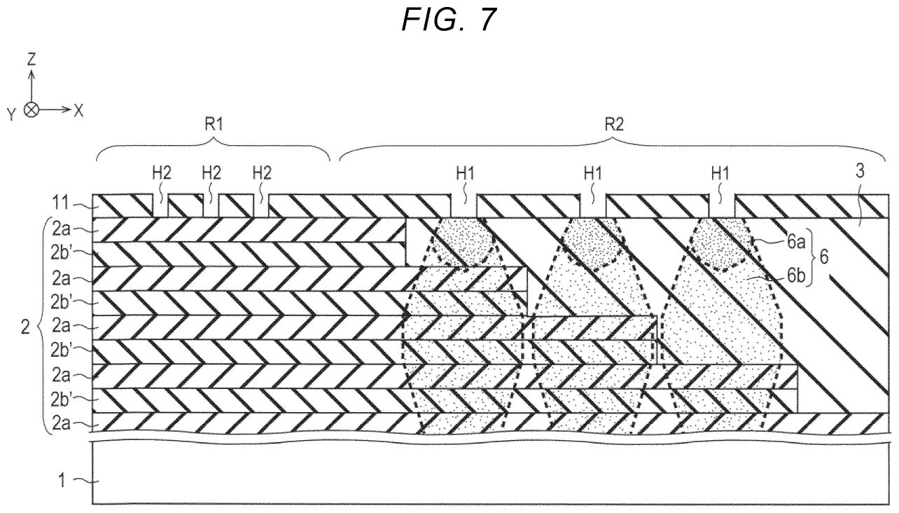

Next, a plurality of openings H2 are formed in the hard mask layer 11 by lithography and RIE (FIG. 7). In FIG. 7, the openings H2 are formed on the flat portion R1.

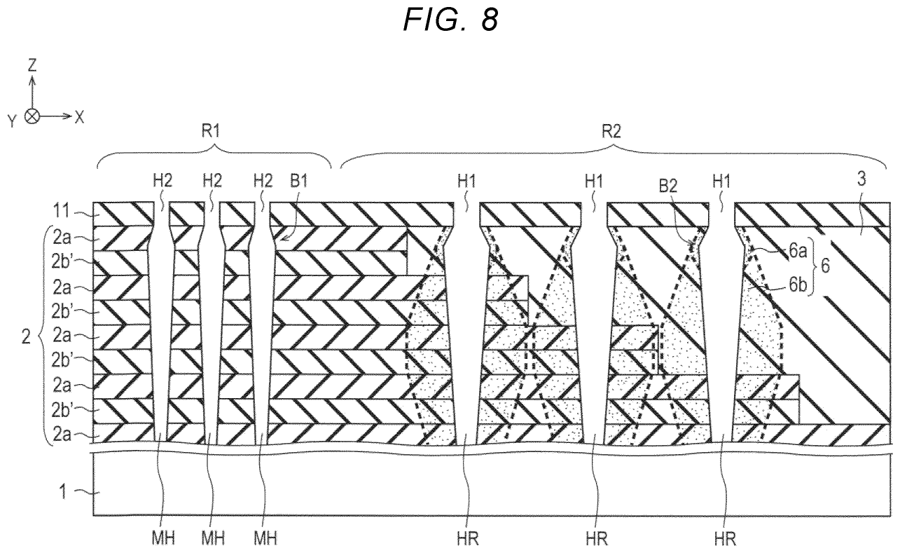

Next, the stacked film 2 and the interlayer insulating film 3 are processed by RIE using the hard mask layer 11 (FIG. 8). As a result, a plurality of the memory holes MH are formed in the flat portion R1 below the openings H2, and a plurality of the beam holes HR are formed in the interlayer insulating film 3 and the stepped portion R2 below the openings H1. In the present embodiment, the memory holes MH and the beam holes HR are simultaneously formed by the RIE.

In the step shown in FIG. 8, each beam hole HR is formed in a corresponding impurity region 6. According to the present embodiment, by forming the beam hole HR in the impurity region 6a, it is possible to reduce the bowing of the beam hole HR. The reason is that, by forming the impurity region 6a having a high P concentration in the interlayer insulating film 3 where the bowing is likely to become large, it is possible to effectively prevent the bowing of the beam hole HR. In addition, according to the present embodiment, by forming the beam hole HR in the impurity region 6b, it is possible to prevent the bowing of the beam hole HR while preventing the deterioration of the breakdown voltage of the semiconductor device. The reason is that, by forming the impurity region 6b having a low P concentration in the stepped portion R2 where the P atoms are likely to cause the deterioration of the breakdown voltage, it is possible to achieve both the prevention of the deterioration of the breakdown voltage and the prevention of the bowing.

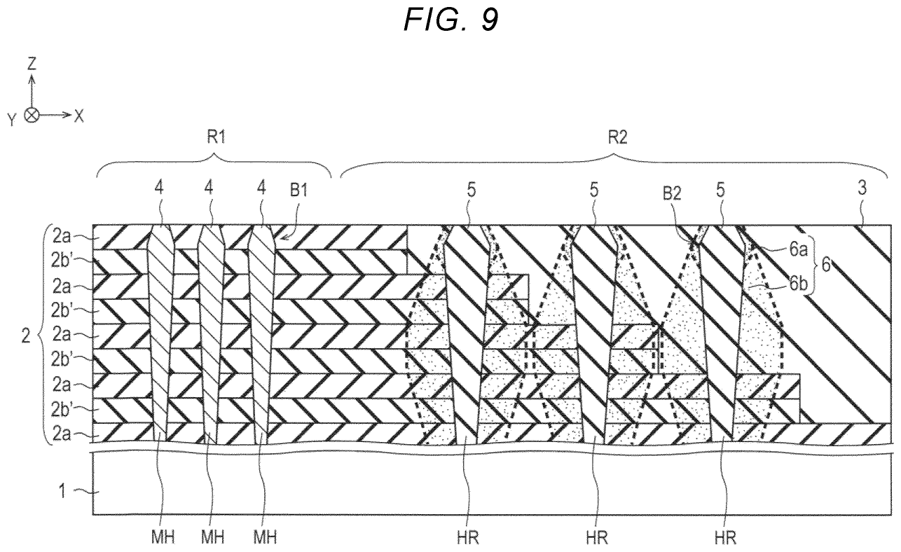

Next, the columnar portion 4 is formed in each memory hole MH, and the beam portion 5 is formed in each beam hole HR (FIG. 9). The columnar portion 4 is formed by sequentially embedding the block insulating film 4a, the charge storage layer 4b, the tunnel insulating film 4c, the channel semiconductor layer 4d, and the core insulating film 4e in each memory hole MH (see FIG. 2). The beam portion 5 is formed by embedding an insulating film (for example, a SiO₂ film) in each beam hole HR. As a result, the beam portion 5 is formed in contact with corresponding impurity regions 6a and 6b. The beam portion 5 may be formed before the columnar portion 4 is formed or may be formed after the columnar portion 4 is formed. In addition, the hard mask layer 11 may be removed before the columnar portion 4 and/or the beam portion 5 is formed, or may be removed after the columnar portion 4 and/or the beam portion 5 is formed.

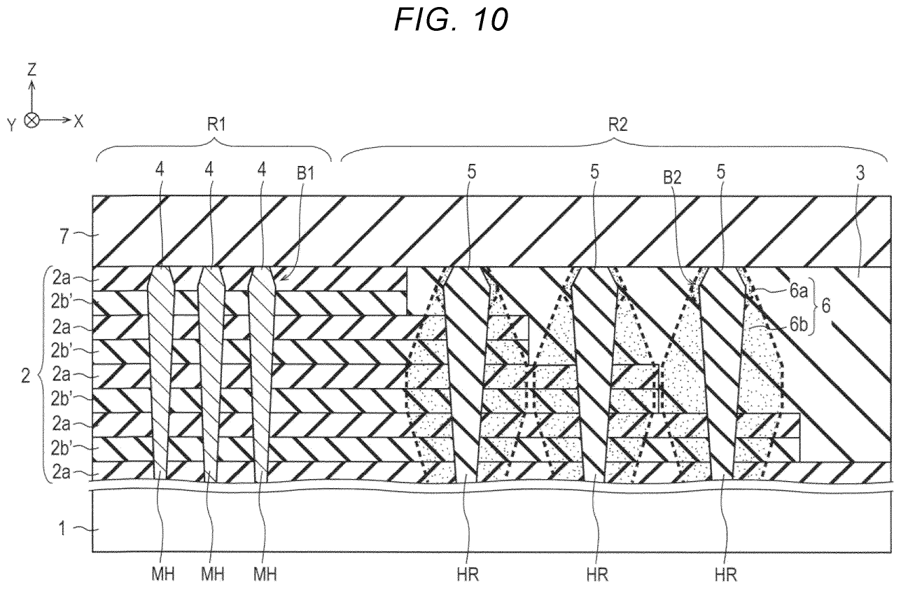

Next, the interlayer insulating film 7 is formed on the stacked film 2, the interlayer insulating film 3, the columnar portion 4, the beam portion 5, and the impurity region 6 (FIG. 10).

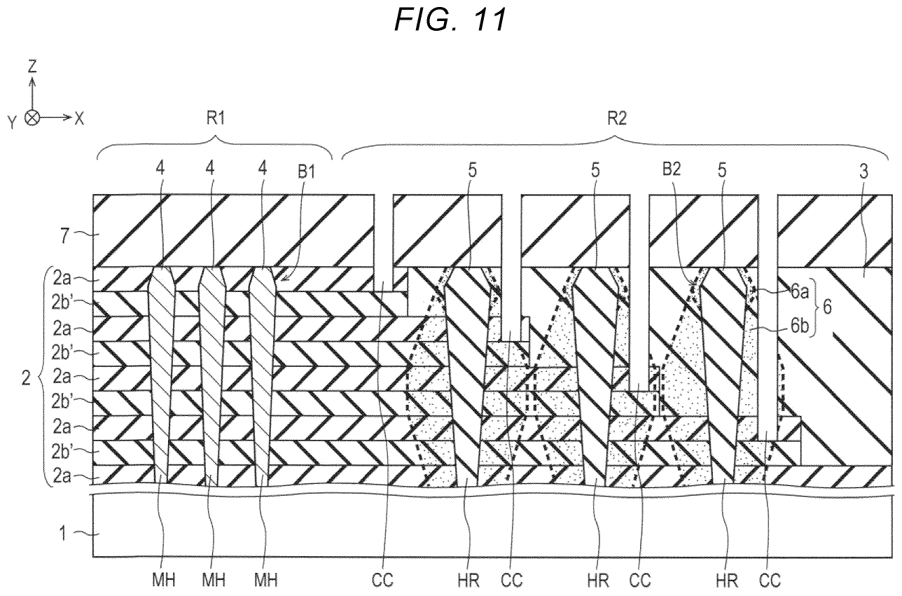

Next, a plurality of the contact holes CC are formed in the interlayer insulating films 7 and 3 and the stacked film 2 by lithography and RIE (FIG. 11). Each contact hole CC is formed to reach an upper surface of a corresponding sacrificial layer 2b′. In FIG. 11, each contact hole CC is formed at a position in contact with a corresponding impurity region 6 (excluding the leftmost contact plug 8 in FIG. 11).

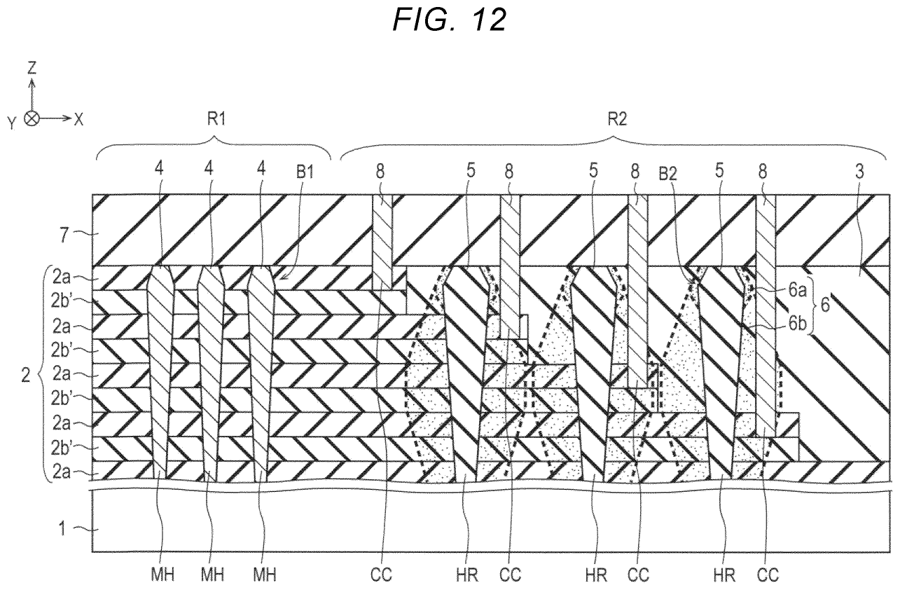

Next, the contact plug 8 is formed in each contact hole CC (FIG. 12). The contact plug 8 is formed by embedding a metal layer in each contact hole CC. As a result, the contact plug 8 is formed in contact with a corresponding impurity region 6 (excluding the leftmost contact plug 8 in FIG. 12).

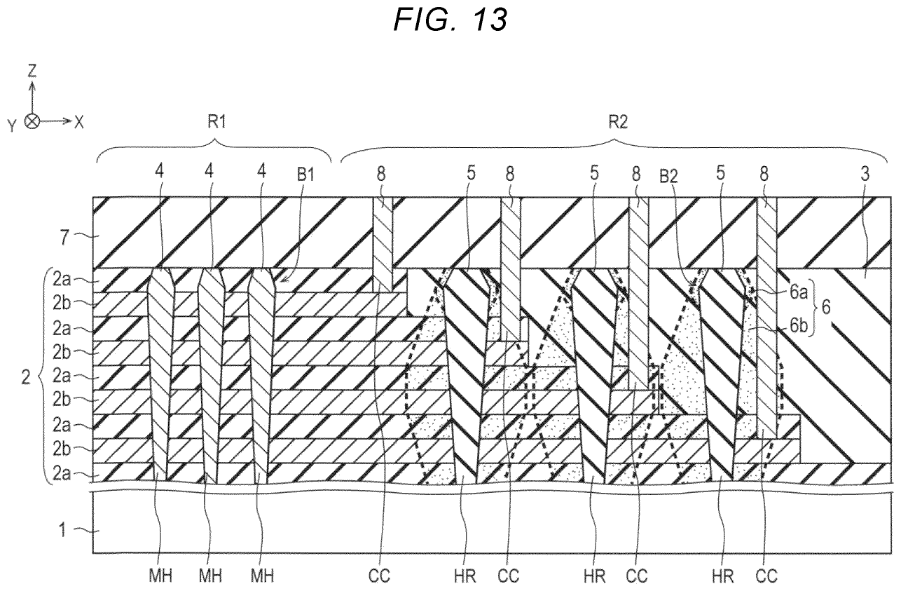

Next, each sacrificial layer 2b′ in the stacked film 2 is replaced with the electrode layer 2b (FIG. 13). As a result, a structure in which the plurality of insulating films 2a and the plurality of electrode layers 2b are alternately provided is formed in the stacked film 2. Further, each contact plug 8 is electrically connected to a corresponding electrode layer 2b. In the step shown in FIG. 13, the sacrificial layer 2b′ is removed from the stacked film 2 by wet etching to form a plurality of voids in the stacked film 2, and a metal layer is embedded in these voids to form the electrode layer 2b in these voids. This process is called a replacement step.

The replacement step may be performed before the contact hole CC is formed. For example, the replacement step may be performed between the step of FIG. 9 and the step of FIG. 10 or between the step of FIG. 10 and the step of FIG. 11. In this case, each contact hole CC is formed to reach an upper surface of a corresponding electrode layer 2b.

In FIG. 13, the insulating film 2a contains the P atoms, and the electrode layer 2b does not contain the P atoms. The reason is that the sacrificial layer 2b′ was replaced with the electrode layer 2b after the impurity region 6 was formed. Meanwhile, the electrode layer 2b may contain a small amount of P atoms by diffusing the P atoms from the insulating film 2a, the interlayer insulating film 3, or the like into the electrode layer 2b after the electrode layer 2b is formed.

In this manner, the semiconductor device shown in FIG. 1 is manufactured.

As described above, each beam portion 5 of the present embodiment is formed in contact with the corresponding impurity regions 6a and 6b. In addition, the P concentration in the impurity region 6b is set lower than the P concentration in the impurity region 6a. Therefore, according to the present embodiment, it is possible to form the beam portion 5 in the beam hole HR with small bowing by preventing the bowing of the beam hole HR by suitable processing. For example, it is possible to prevent the bowing of the beam hole HR while preventing the deterioration of the breakdown voltage of the semiconductor device.

The impurity region 6 includes two regions (impurity regions 6a and 6b) having different P concentrations in the present embodiment, and may include three or more regions having different P concentrations. In addition, the P concentration in the impurity region 6 may change continuously depending on the position in the impurity region 6. For example, the impurity region 6 may include the impurity regions 6a and 6b in a form in which a boundary surface between the impurity region 6a and the impurity region 6b is not clear. In this case, the impurity regions 6a and 6b may be regarded as two regions or as one region. This also applies to second and third embodiments described below.

### Second Embodiment

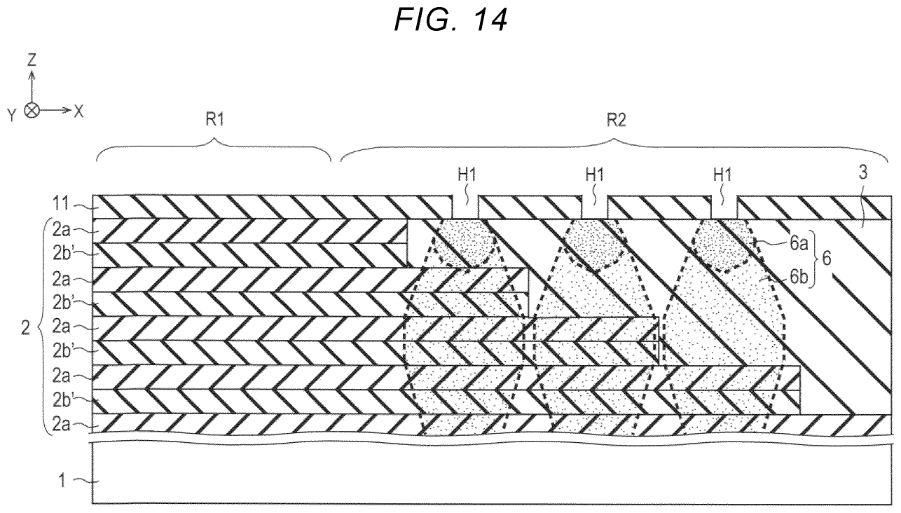

FIGS. 14 to 20 are cross-sectional views showing a manufacturing method of the semiconductor device according to the second embodiment. The method shown in FIGS. 14 to 20 is used for manufacturing the semiconductor device shown in FIG. 1 in a different flow from the method shown in FIGS. 3 to 13.

First, the steps of FIGS. 3 to 6 are performed. FIG. 14 shows the same state as the state shown in FIG. 6.

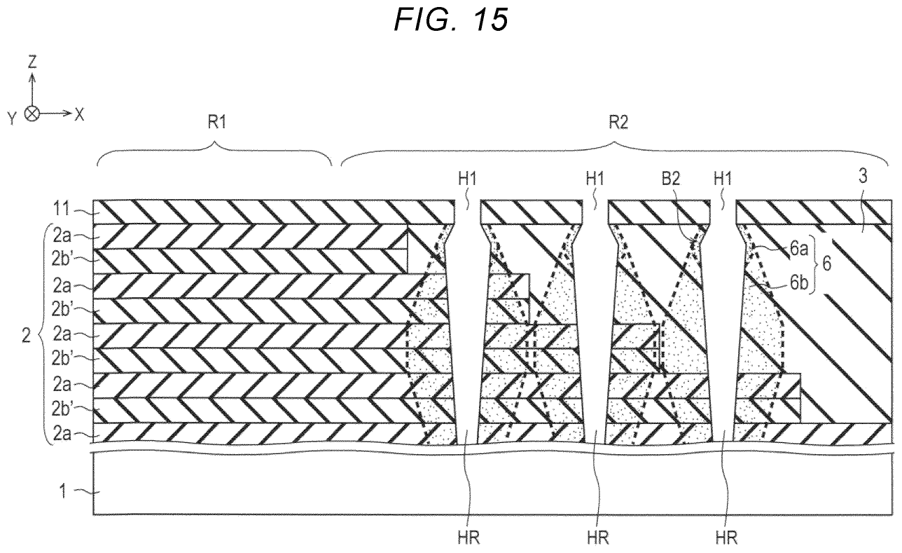

Next, the stacked film 2 and the interlayer insulating film 3 are processed by RIE using the hard mask layer 11 (FIG. 15). As a result, the plurality of beam holes HR are formed in the interlayer insulating film 3 and the stepped portion R2 below the openings H1.

In the step shown in FIG. 15, each beam hole HR is formed in a corresponding impurity region 6, as in the step shown in FIG. 8. According to the present embodiment, by forming the beam hole HR in the impurity region 6a, it is possible to reduce the bowing of the beam hole HR. In addition, according to the present embodiment, by forming the beam hole HR in the impurity region 6b, it is possible to prevent the bowing of the beam hole HR while preventing the deterioration of the breakdown voltage of the semiconductor device.

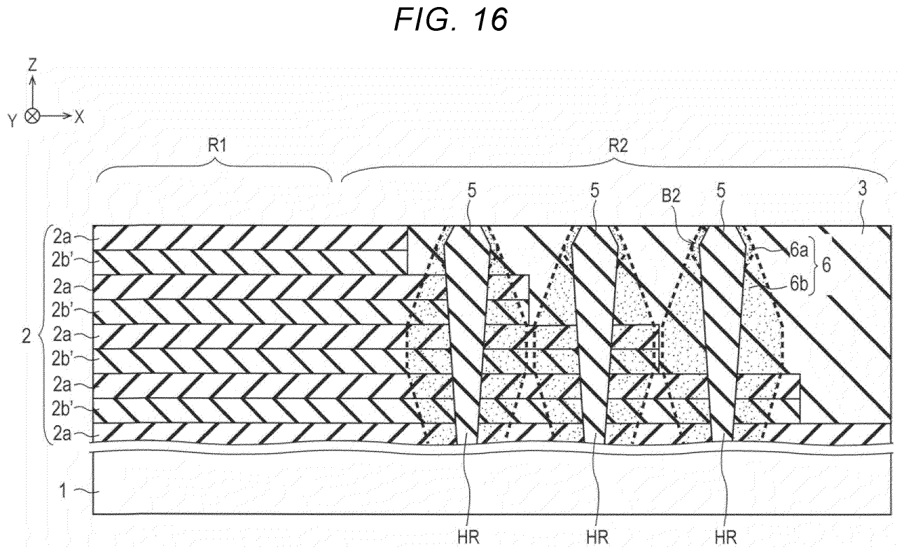

Next, the beam portion 5 is formed in each beam hole HR (FIG. 16). The beam portion 5 is formed by embedding an insulating film (for example, a SiO₂ film) in each beam hole HR. As a result, the beam portion 5 is formed in contact with corresponding impurity regions 6a and 6b. The hard mask layer 11 may be removed before the beam portion 5 is formed, or may be removed after the beam portion 5 is formed.

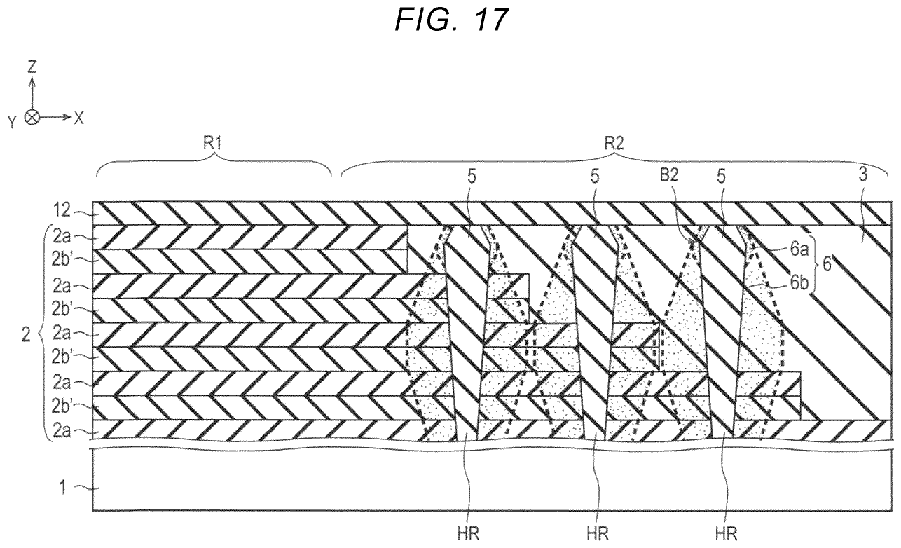

Next, a hard mask layer 12 is formed on the flat portion R1 and the interlayer insulating film 3 (FIG. 17). The hard mask layer 12 is, for example, a C layer.

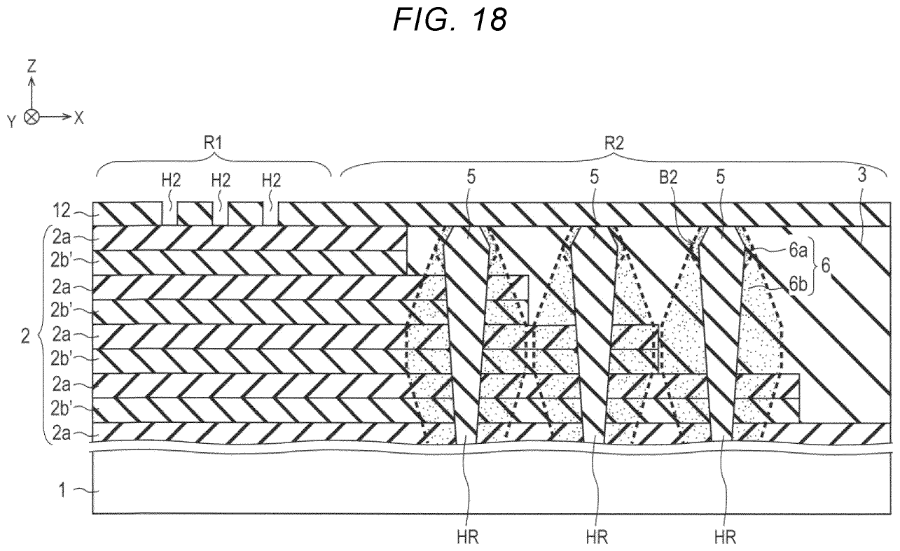

Next, a plurality of openings H2 are formed in the hard mask layer 12 by lithography and RIE (FIG. 18). In FIG. 18, the openings H2 are formed on the flat portion R1.

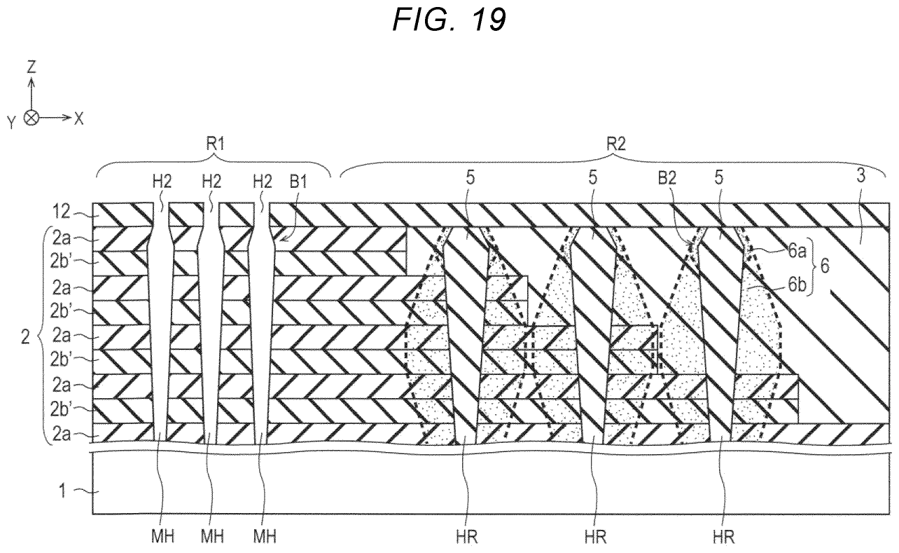

Next, the stacked film 2 is processed by RIE using the hard mask layer 12 (FIG. 19). As a result, the plurality of memory holes MH are formed in the flat portion R1 below the openings H2. In the present embodiment, the memory holes MH and the beam holes HR are sequentially formed, and the contact hole CC is formed in a subsequent step.

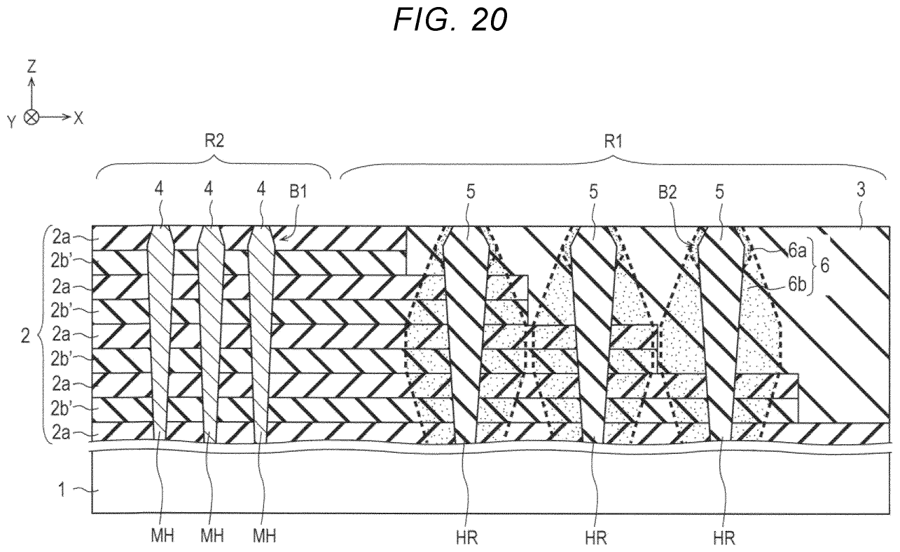

Next, the columnar portion 4 is formed in each memory hole MH (FIG. 20). The columnar portion 4 is formed by sequentially embedding the block insulating film 4a, the charge storage layer 4b, the tunnel insulating film 4c, the channel semiconductor layer 4d, and the core insulating film 4e in each memory hole MH (see FIG. 2). The hard mask layer 12 may be removed before the columnar portion 4 is formed, or may be removed after the columnar portion 4 is formed.

Thereafter, the steps shown in FIGS. 10 to 13 are performed. In this manner, the semiconductor device shown in FIG. 1 is manufactured.

According to the present embodiment, as in the first embodiment, it is possible to form the beam portion 5 in the beam hole HR with small bowing by preventing the bowing of the beam hole HR by suitable processing. The beam hole HR of the present embodiment is formed before the memory hole MH is formed, or may be formed after the memory hole MH is formed.

### Third Embodiment

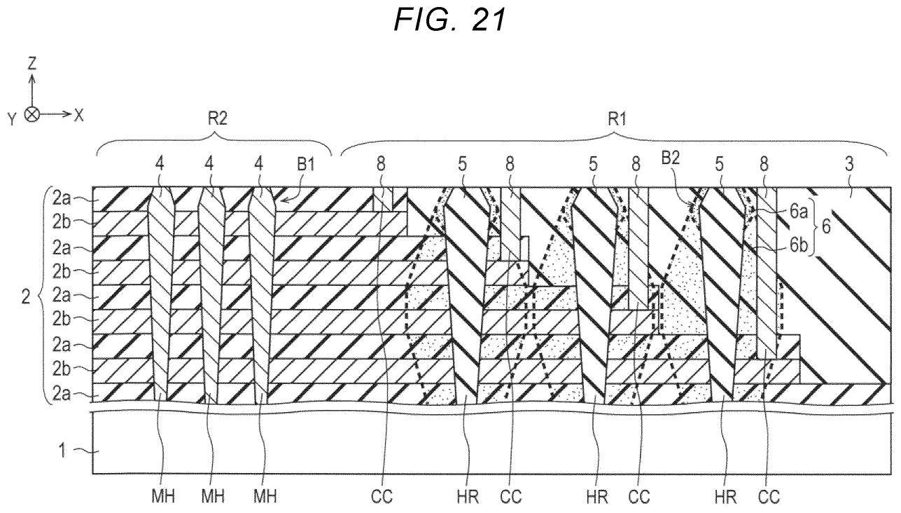

FIG. 21 is a cross-sectional view showing a structure of the semiconductor device according to the third embodiment.

The semiconductor device according to the present embodiment (FIG. 21) has the same structure as the semiconductor device according to the first embodiment (FIG. 1). Meanwhile, the semiconductor device according to the present embodiment does not include the interlayer insulating film 7. Therefore, each contact plug 8 of the present embodiment does not include a portion provided in the interlayer insulating film 7. In the present embodiment, as described below, the memory hole MH, the beam hole HR, and the contact hole CC are simultaneously formed by the same RIE.

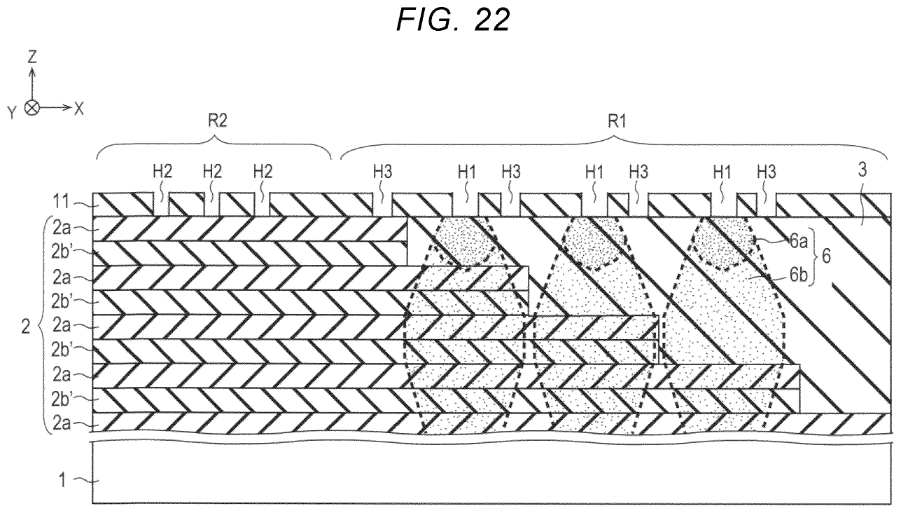

FIGS. 22 to 25 are cross-sectional views showing a manufacturing method of the semiconductor device according to the third embodiment.

First, after the steps of FIGS. 3 to 6 are performed, a plurality of openings H2 and a plurality of openings H3 are formed in the hard mask layer 11 by lithography and RIE (FIG. 22). In FIG. 22, the opening H2 is formed on the flat portion R1, and the opening H3 is formed on the interlayer insulating film 3.

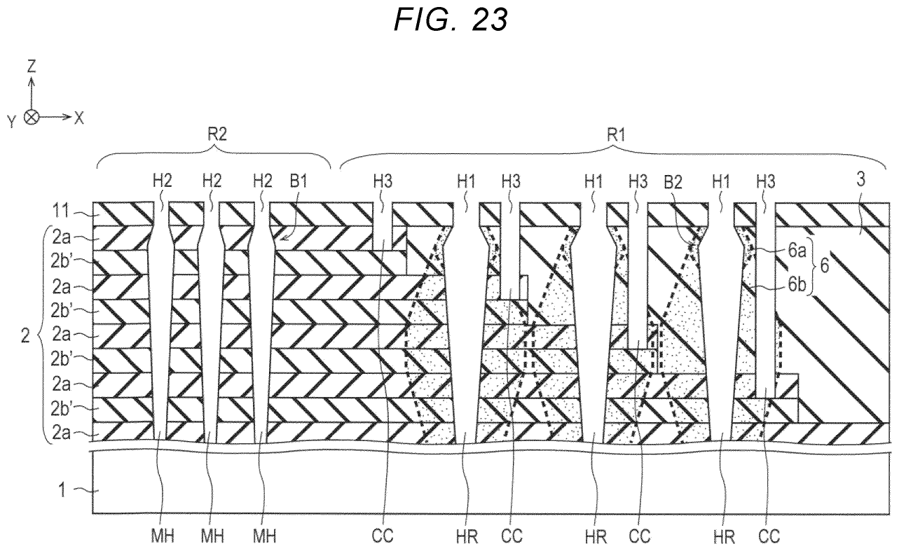

Next, the stacked film 2 and the interlayer insulating film 3 are processed by RIE using the hard mask layer 11 (FIG. 23). As a result, a plurality of the memory holes MH are formed in the flat portion R1 below the openings H2, a plurality of the beam holes HR are formed in the interlayer insulating film 3 and the stepped portion R2 below the openings H1, and a plurality of the contact holes CC are formed in the interlayer insulating film 3 and the stepped portion R2 below the openings H3. In the present embodiment, the memory hole MH, the beam hole HR, and the contact hole CC are simultaneously formed by the RIE.

In the step shown in FIG. 23, each beam hole HR is formed in a corresponding impurity region 6, as in the step shown in FIG. 8 or the step shown in FIG. 15. According to the present embodiment, by forming the beam hole HR in the impurity region 6a, it is possible to reduce the bowing of the beam hole HR. In addition, according to the present embodiment, by forming the beam hole HR in the impurity region 6b, it is possible to prevent the bowing of the beam hole HR while preventing the deterioration of the breakdown voltage of the semiconductor device.

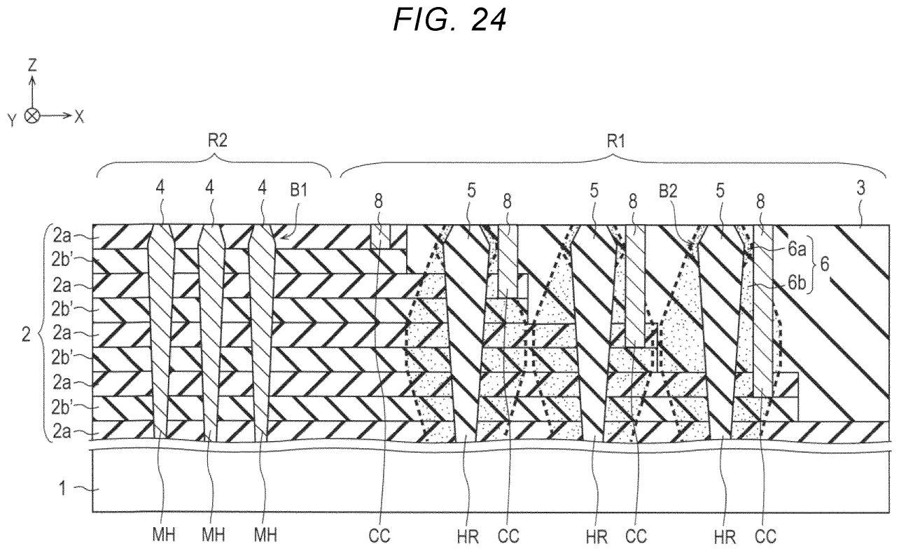

Next, the columnar portion 4 is formed in each memory hole MH, the beam portion 5 is formed in each beam hole HR, and the contact plug 8 is formed in each contact hole CC (FIG. 24). The columnar portion 4 is formed by sequentially embedding the block insulating film 4a, the charge storage layer 4b, the tunnel insulating film 4c, the channel semiconductor layer 4d, and the core insulating film 4e in each memory hole MH (see FIG. 2). The beam portion 5 is formed by embedding an insulating film in each beam hole HR, and is formed in contact with corresponding impurity regions 6a and 6b. The contact plug 8 is formed by embedding a metal layer in each contact hole CC, and is formed in contact with a corresponding impurity region 6 (excluding the leftmost contact plug 8 in FIG. 24). The columnar portion 4, the beam portion 5, and the contact plug 8 may be formed in any order. In addition, the hard mask layer 11 may be removed before the columnar portion 4, the beam portion 5, and/or the contact plug 8 is formed, or may be removed after the columnar portion 4, the beam portion 5, and/or the contact plug 8 is formed.

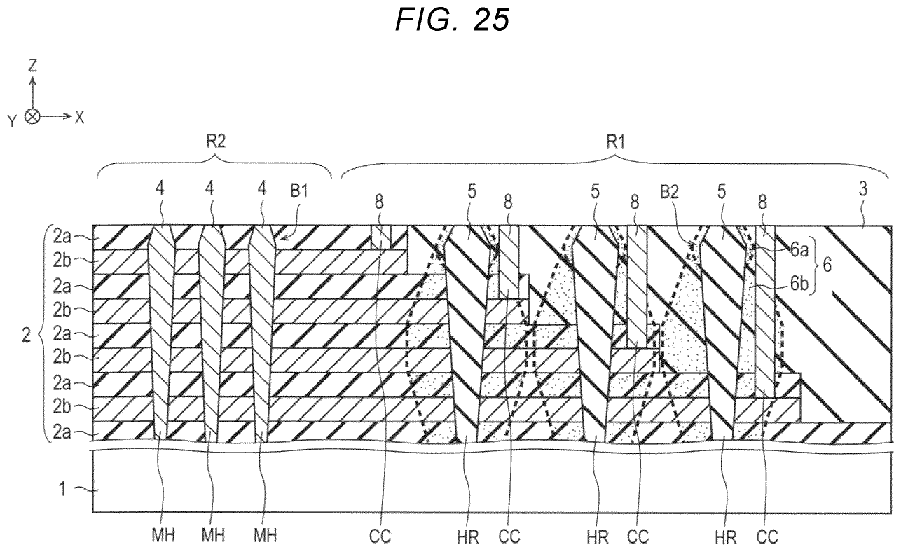

Next, each sacrificial layer 2b′ in the stacked film 2 is replaced with the electrode layer 2b (FIG. 25). As a result, a structure in which the plurality of insulating films 2a and the plurality of electrode layers 2b are alternately provided is formed in the stacked film 2. Further, each contact plug 8 is electrically connected to a corresponding electrode layer 2b. The step shown in FIG. 25 is capable of being performed in the same manner as the step shown in FIG. 13.

In this manner, the semiconductor device shown in FIG. 21 is manufactured.

According to the present embodiment, as in the first and second embodiments, it is possible to form the beam portion 5 in the beam hole HR with small bowing by preventing the bowing of the beam hole HR by suitable processing.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a stacked film including a plurality of electrode layers and a plurality of first insulating films alternately stacked in a first direction, wherein the stacked film includes a first portion with a non-stepped shape and a second portion with a stepped shape;
a second insulating film provided on the second portion of the stacked film;
a columnar portion extending through the first portion in the first direction and including a charge storage layer and a semiconductor layer;
a third insulating film extending through the second portion and the second insulating film in the first direction;
a plug connected to any of the electrode layers in the second portion; and
a first region provided in the second portion and the second insulating film, the first region including a first element,
wherein a concentration of the first element in the first region is higher than a concentration of the first element in a region outside the first region in the second insulating film, and
at least one of the third insulating film or the plug is in contact with the first region.

2. The semiconductor device according to claim 1,
wherein the first region includes an upper region including the first element with a first concentration and a lower region provided below the upper region and including the first element with a second concentration lower than the first concentration.

3. The semiconductor device according to claim 1,
wherein the third insulating film or the plug is provided in the first region.

4. The semiconductor device according to claim 2,
wherein at least one of the third insulating film or the plug is in contact with the upper region and the lower region.

5. The semiconductor device according to claim 2,
wherein the upper region includes at least the second insulating film, and
the lower region includes at least the second portion.

6. The semiconductor device according to claim 1,
wherein the first region includes the first insulating film of the second portion.

7. The semiconductor device according to claim 1,
wherein the first element is an impurity element in the second portion and the second insulating film.

8. The semiconductor device according to claim 1,
wherein the first element is phosphorus (P).

9. The semiconductor device according to claim 1,
wherein the first concentration is between 1.0×10²¹ and 1.0×10²² atoms/cm³, and
the second concentration is between 1.0×10²⁰ and 5.0×10²¹ atoms/cm³.

10. A manufacturing method of a semiconductor device, comprising:
forming a stacked film including a plurality of first layers and a plurality of first insulating films alternately stacked in a first direction, wherein the stacked film includes a first portion with a non-stepped shape and a second portion with a stepped shape;
forming a second insulating film on the second portion;
forming a first region including a first element in the second portion and the second insulating film;
forming a columnar portion extending through the first portion in the first direction and including a charge storage layer and a semiconductor layer;
forming a third insulating film extending through the second portion and the second insulating film in the first direction;
replacing the plurality of first layers in the stacked film with a plurality of electrode layers, respectively; and
forming a plug on any of the first layers or on any of the electrode layers in the second portion,
wherein a concentration of the first element in the first region is higher than a concentration of the first element in a region outside the first region in the second insulating film, and
the at least one of third insulating film or the plug is formed in contact with the first region.

11. The manufacturing method of a semiconductor device according to claim 10,
wherein the first region includes an upper region that includes the first element with a first concentration and a lower region that is provided below the upper region and includes the first element with a second concentration lower than the first concentration.

12. The manufacturing method of a semiconductor device according to claim 10, further comprising forming the third insulating film or the plug after forming the first region.

13. The manufacturing method of a semiconductor device according to claim 11, further comprising forming the lower region after forming the upper region.

14. The manufacturing method of a semiconductor device according to claim 10, further comprising forming the first region in the first layer and the first insulating film of the second portion.

15. The manufacturing method of a semiconductor device according to claim 10, further comprising forming the first region by implanting ions of the first element into the second insulating film and the second portion.

16. The manufacturing method of a semiconductor device according to claim 15,
wherein, after implanting the ions of the first element, an etching rate of the second insulating film and the second portion in the first region is larger than an etching rate of the second insulating film and the second portion outside the first region.

17. The manufacturing method of a semiconductor device according to claim 15, further comprising:
forming a mask layer on the second insulating film; and
forming an opening in the mask layer,
wherein the first region is formed by implanting the ions of the first element into the second insulating film and the second portion from the opening.

18. The manufacturing method of a semiconductor device according to claim 17, further comprising:
forming a recess in the second insulating film and the second portion after forming the first region,
wherein at least one of the third insulating film or the plug is formed in the recess to be in contact with the first region.

19. The manufacturing method of a semiconductor device according to claim 10, further comprising:
forming a first recess extending through the first portion in the first direction;
forming a second recess extending through the second portion and the second insulating film in the first direction; and
forming a third recess on any of the first layers or on any of the electrode layers in the second portion,
wherein the columnar portion, the third insulating film, and the plug are formed in the first recess, the second recess, and the third recess, respectively.

20. The manufacturing method of a semiconductor device according to claim 18,
wherein two or more of the first recess, the second recess, and the third recess are simultaneously formed.
